(19) United States
(12) Patent Application Publication
(10) Pub. No.: US 2002/0123251 A1
(43) Pub. Date: Sep. 5, 2002

(54) Apparatus and method for providing reliable electrical connector for a printed circuit board in a computer

(76) Inventors: Alexander I. Yatskov, City of Kenmore, WA (US); Stephen V.R. Hellriegel, City of Bainbridge Island, WA (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/797,786

(22) Filed: Mar. 2, 2001

(51) Int. Cl. H05K 1/00

(52) U.S. Cl. 439/65

(57) ABSTRACT

A reliable power supply connection to a printed circuit board. A canted coil spring in a channel is coupled to a printed circuit board. The individual chips, electrical components and other circuits on the printed circuit board have their respective power supply terminals connected to the canted coil spring channel member. The printed circuit board can be easily slid into, and removed from a frame assembly with a high degree of reliability in making the electrical connection having a low impedance each time the circuit board is placed into the frame of the computer. Furthermore, as the board is slid into the computer, the coil spring rubs against the electrical surface to which it is going to make contact, abrading the surface and removing any debris, or buildup which may have occurred both on the power supply pad and on the spring itself. A fresh, clean metal connection is therefore made each time the printed circuit board is placed into, or removed from the computer frame. According to one embodiment, the canted coil spring is retained in a preset sloped position to ensure that it does not snag or otherwise connect to other portions of the frame when it is being removed or inserted into the system.

### TECHNICAL FIELD

This invention relates to electrical connectors, and more particularly to electrical connectors for coupling circuits on circuit substrates, such as printed circuit boards.

### BACKGROUND OF THE INVENTION

Many computing devices, such as desktop computers, workstations, mainframe and super-computers employ multiple printed circuit boards (“PCB”) that include various microprocessors, printed circuits and other components that must be electrically coupled together to transmit data and/or power. The electrical traces on one or more layers of the PCB form the printed circuits and typically terminate in one or more terminals or contacts for making connections. A single failed or intermittent connection can result in large amounts of “down-time” for the computing device, and costly troubleshooting by highly skilled technicians.

Highly parallel processing super-computers present a particularly significant problem in terms of space constraints. These computers rely on a high number of connections between circuit boards that each carry one or more microprocessors. The nature of parallel processing places high demands on the timing of signals, including clock signals across the various computer components. In an effort to improve the timing of the signals, the PCBs are spaced relatively close together to reduce the length of the connections between the PCBs. The tight spacing hinders the ability of technicians to access particular computer components, such as the PCBs and electrical connectors. This presents a particular problem to computer manufacturers and owners who desire a modular design that permits failed components to be quickly and easily replaced. If serviceable, a modular design would also permit the addition of new or additional processors as desired, for example when more processing power is required or when the processors become more affordable. This could significantly extend the life of the computing device.

A highly reliable and precise electrical connector is required to couple circuits between printed circuit boards, particularly for providing a supply voltage to the circuits. Additionally the connection should not cause significant voltage drops.

### SUMMARY OF THE INVENTION

Under one aspect of the invention, a circuit substrate includes an electrical connector having a conductive channel surface in electrical communication with a canted coil spring conductor and a conductive contact surface, to couple circuits on the circuit substrate to a power supplying substrate.

A frame assembly is provided for housing a printed circuit board. The printed circuit board has mounted thereon a plurality of conductive channel members, each having a canted coil spring therein. Within the frame assembly a top conductive plate and a bottom conductive plate are positioned. Each of the conductive plates has thereon a power supply pad which is composed of an electrically conductive metal. The power supply pad is positioned so as to be in electrical contact with the respective canted coil springs when the printed circuit board is positioned inside the frame assembly. This provides a highly reliable, low resistance electrical contact for a power supply to the printed circuit board. Furthermore, while the printed circuit board is being inserted the canted coil spring frictionally rubs along the power supply pads within the frame assembly. This frictional rubbing removes any thin coatings of debris, such as an oxide, which may have built up between the two surfaces so as to provide a low impedance highly conductive contact between the coil spring and the power supply plate.

One advantage of the present invention is that the high power requirements of a printed circuit board having many microprocessors thereon can be easily provided for according to the present invention. A further benefit of the present invention is that each time the printed circuit board is inserted into, or removed from, the frame assembly, assurances are made that the electrical contact for providing power to the printed circuit board will be provided without damage to the printed circuit board, or the frame assembly.

### BRIEF DESCRIPTION OF THE DRAWINGS

In the drawings, identical reference numbers identify similar elements or acts. The sizes and relative positions of elements in the drawings are not necessarily drawn to scale and various elements and portions of elements may be are arbitrarily enlarged and positioned to improve drawing legibility.

FIG. 1 is an isometric view of a frame according to the present invention for holding a printed circuit board having chips thereon.

FIG. 2 is an isometric view of the module of printed circuit boards ready for being inserted into the frame of FIG. 1.

FIG. 3 is an isometric view of a module of printed circuit boards according to the present invention showing a channel for a canted coil spring conductor.

FIG. 4 is a right elevational view of a block diagram of the module of FIG. 3, as it is inserted into the frame with the canted coil spring conductor being moved into a position to provide electrical connection to a portion of the circuit board.

FIG. 5 is an isometric view of the electrical connector with the canted coil spring conductor in the channel.

FIG. 6 is an isometric view of a circuit board having electrical connection made according to the present invention.

FIG. 7 is an isometric view of the channel having a canted coil spring therein and a bracket for mounting to the circuit board of FIG. 6.

FIG. 8 is a top view of the channel coupled to the circuit board without the canted coil spring present.

FIG. 9 is a side elevational view of the retainer.

FIG. 10 is a side elevational view of the canted coil spring conductor received about the retainer.

FIG. 11 is a rear elevational view of the canted coil spring conductor received about the retainer.

### DETAILED DESCRIPTION OF THE INVENTION

In the following description, certain specific details are set forth in order to provide a thorough understanding of various embodiments of the invention. However, one skilled in the art will understand that the invention may be practiced without these details. In other instances, well-known structures associated with computers, printed circuit boards, circuits, mechanical clamps and electrical connectors have not been shown or described in detail to avoid unnecessarily obscuring descriptions of the embodiments of the invention.

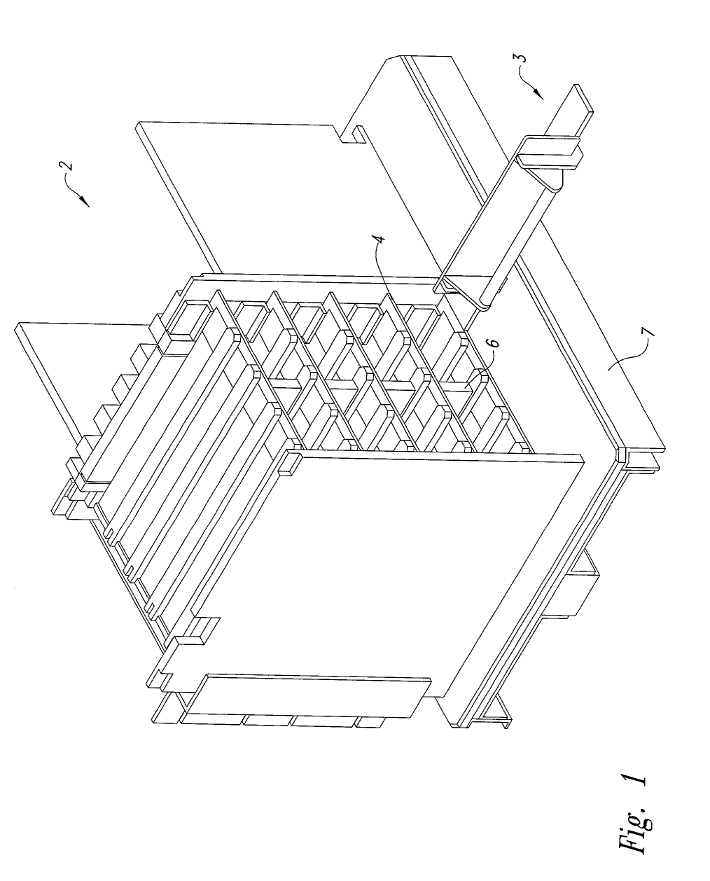

FIG. 1 shows a housing 2 for a super computer according to principles of the present invention. While the housing 2 is described as being for a super computer, it may, of course be for any acceptable arrangement of electrical components having the need to be electrically interconnected to each other. For example, the housing of FIG. 1 may be used for a large number of audio amplification circuits, individual computer units each operating as a separate mother board and not forming a super computer, a plurality of data storage systems, or any other electrical component assembly which is convenient for holding in a common housing 2. The electrical connection principles as described herein, while particular reference is given for use with a super computer, may also be used with any other electrical components stored in a housing similar to that of FIG. 1 or, even a much smaller housing, such as a housing having only one or two separate levels rather than the four levels shown in FIG. 1.

The housing 2 includes a plurality of support boards 6, in the examples shown there being five support boards forming four individual levels into which separate electrical circuit components on printed circuit boards can be positioned.

A loading member 3 is positioned for loading the printed circuit boards into the housing 2 as described later herein. A plurality of support members 6 may also be provided as needed to hold the individual support layers a known distance from each other in any rigid, reliable connection. Further, base support 7, or any other suspension or support system may also be provided as needed.

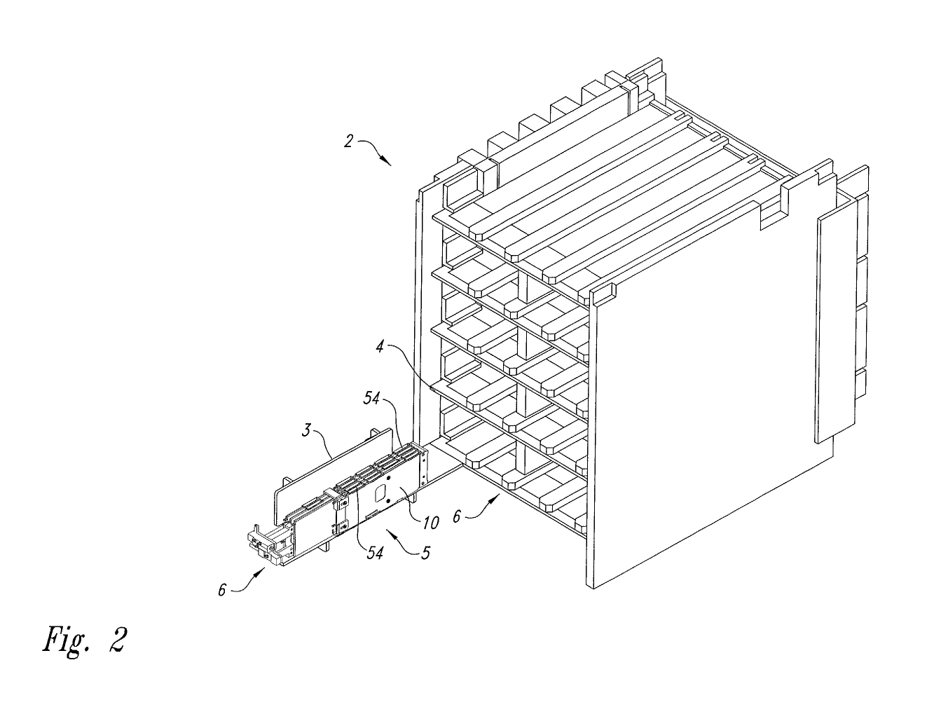

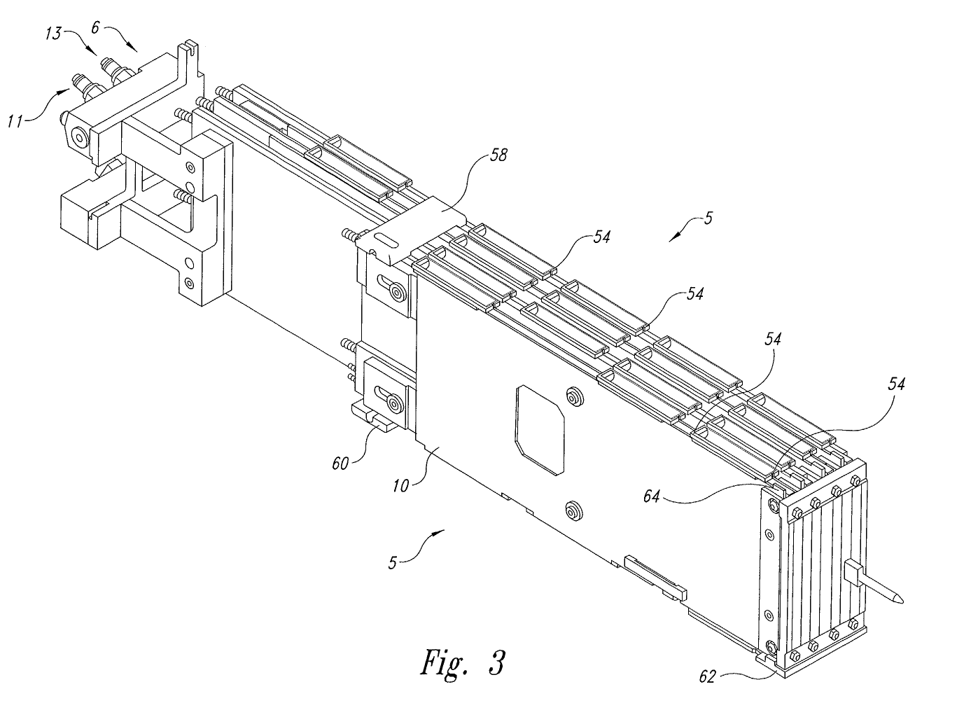

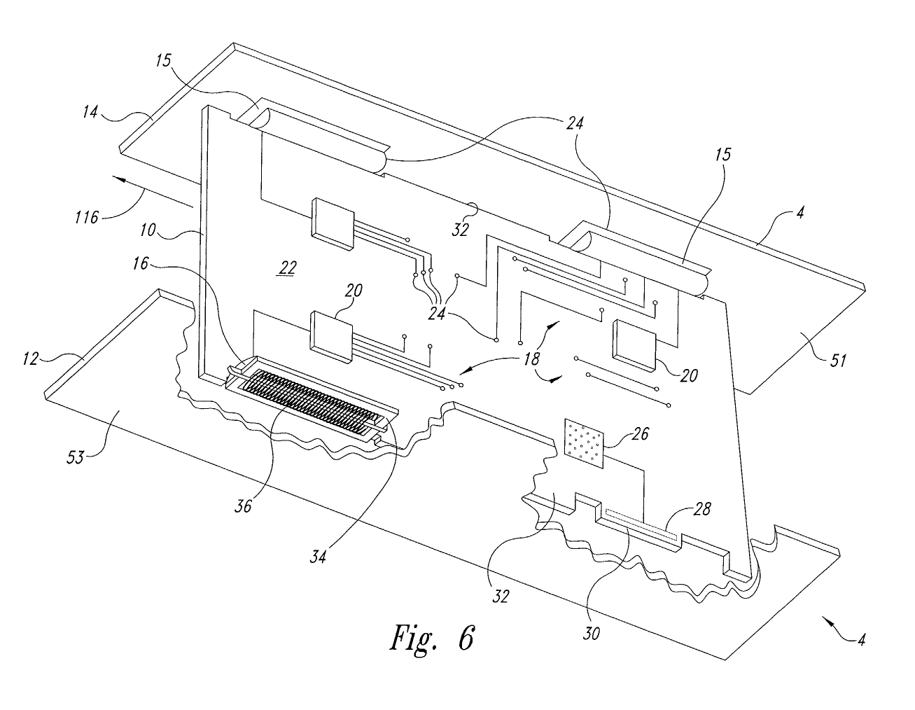

FIG. 2 shows the housing 2 into which a group of printed circuit boards is about to be loaded. The printed circuit boards are formed into a moveable unit referred to as a resource module 5. The resource module 5 has, in the examples shown, four printed circuit boards each of which have mounted thereon a large number of integrated circuits. The individual printed circuit boards are shown, in more detail, in FIG. 6. A plurality of the printed circuit boards of the type shown in FIG. 6 are coupled together to provide the resource module 5 as shown in FIGS. 2 and 3. The resource module 5 has a manifold 6 at one end thereof. The manifold 6 is positioned outside of the housing 2 so that it may easily be connected to components and systems outside the housing 2. These may be, for example, cooling fluid supply hoses, brackets for holding the resource module 5 in position, and, in some cases, may also include electrical circuit connectors.

The resource module 5 may, in some instances, have considerable weight, such as in the range of 60-80 pounds. In one embodiment, the weight exceeds 70 pounds, and therefore it is somewhat difficult for loading and unloading in a reliable fashion. In order to assist in the loading and unloading of the resource module 5, a loading assembly 3 is provided. The loading assembly 3 is coupled to the front of the housing 2 with solid, reliable connectors so as to hold the loading assembly 3 in position while the resource module 5 is placed thereon and then slid forward into position into the housing 2, as will now be described.

FIG. 3 shows the resource module 5 from FIG. 2, enlarged. The resource module 2 is composed of a plurality of printed circuit boards 10 of the type described in more detail with respect to FIG. 6. Mounted at the bottom of the resource module 5 are support shoes 62 and 60, support shoe 62 being at a front end thereof and support shoe 60 being at a central portion thereof so as to hold the weight of the resource module 5. The shoes 62 and 60 are preferably composed of a durable, strong and also low friction material. For example, the shoes 62 and 60 may be composed of a high density plastic coated with Teflon, or of a Teflon material.

The manifold 6 at one of the resource module 5 is coupled to the printed circuit boards to provide mechanical support, as well as cooling fluid connection. Cooling fluid nipples 11 and 13 are positioned on the manifold 6. Hoses are connected to the cooling fluid nipples 11 and 13 so that water may circulate around the printed circuit boards, removing heat from the integrated circuits which are positioned thereon.

The top of the resource module also includes support shoes 58 and 64. The support shoes 58 and 64 contact the upper surface of the frame member 4, for holding the resource module 5 in a defined, specific position with respect to both the upper frame member 4 and the lower frame member 4 on which it rests.

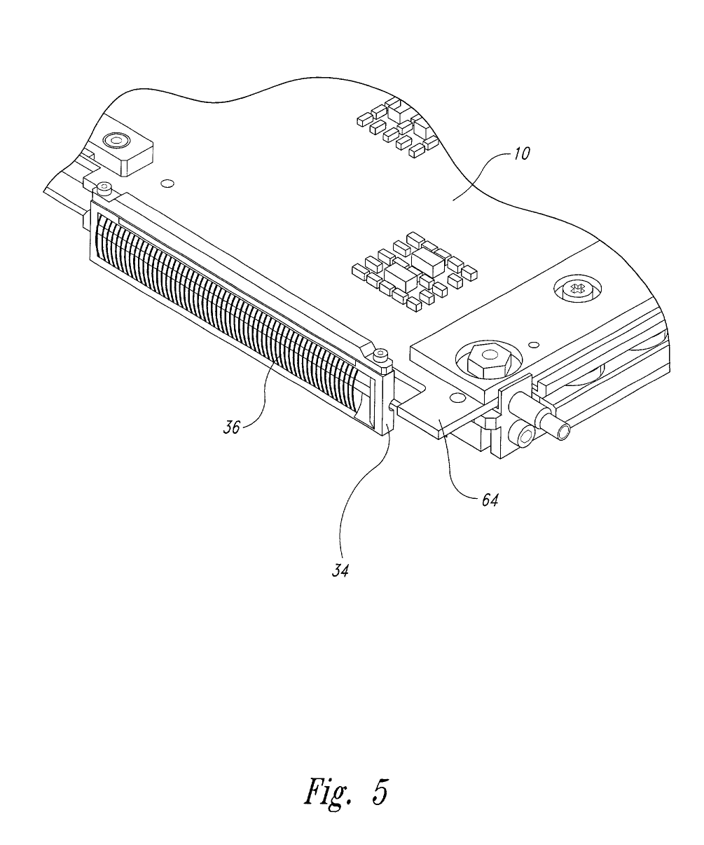

Positioned on the top and bottom of the individual printed circuit boards are channels 54. Electrical connectors are mounted inside channels 54, as described in more detail herein with respect to FIGS. 5-11.

The resource module 5 is positioned within the frame 10 by placing it on the loader 3. When the resource module is properly positioned it is slid forward, along the loader 3 and enters into the housing 2 as will now be described in more detail.

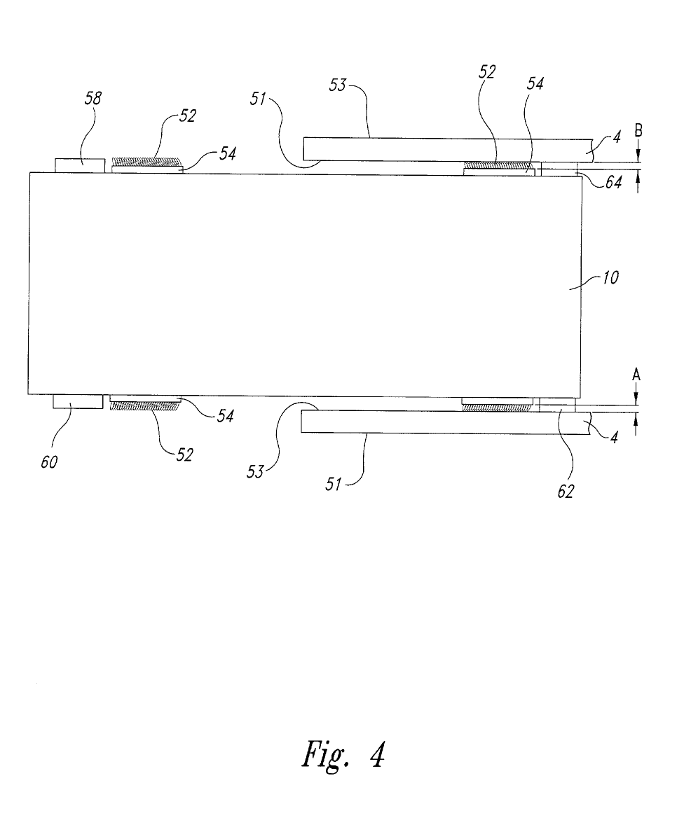

FIG. 4 shows the resource module 5, in a schematic-type view for ease of illustration as it is sliding into the housing 2. According to the present invention, a canted coil spring 52 is positioned within each of the channels 54. The canted coil spring 52 is composed of an electrically conductive metal, and preferably coated with a highly conductive metal, such as hard gold, a copper alloy or some other metal which is known to be highly conductive and also resistant to corrosion.

As can be seen in FIG. 4, the canted coil spring 52 extends out of the channel 54 so as to provide electrical contact with the bottom surface 51 of the top frame member 4 and the top surface 53 of the bottom frame member 4. As the resource module 5 is slid into the housing 2, the canted coil spring 52 rubs the electrical connectors of the frame member 4 in a frictional, scraping fashion. As the conductive canted coil spring 52 scraps along the electrical conductive member pads on the bottom surface 51 of the frame 4, it provides several advantageous results. First, the debris, corrosion buildup, and thin oxide layer which often form on the outer surface of a metal is scraped away. Further, the scraping provides a fresh metal interaction between both the canted coil spring and the conductive pads positioned on the frame 4. Therefore, a reliable, low impedance connection is assured between the printed circuit board and the power supply pads of the housing 2 for the computer assembly.

As can be seen, the coils 52 extend for a slight distance higher than the shoes 58 and 64. They also extend beyond the bottom shoes 60 and 62. This ensures that the canted coil spring is brought into mechanical, as well as electrical, contact of the conductive pads on the frame members 4 while it is slid into position.

Dimension A of FIG. 4 represents the clearance between the rim of the channel 54 and the top surface 53 of the frame member 4. This dimension is determined by the thickness and placement of the shoes 60 and 62. Dimension B represents the clearance between the rim of the channel 54 and the bottom surface 51 of the frame member 4, above the resource module. This dimension is determined by the thickness and placement of the shoes 60 and 62, as well as the distance between the support boards 4 above and below the resource module. In this configuration, the canted coil springs 52 in the channels 54 on the top of the resource module must be capable of tolerating the sum of the allowed variations in the values of dimensions A and B.

The nature of the canted coil spring 52 is such, that through a range of about 10% to 25% compression the “support force”, or the force with which the spring resists compression, varies only slightly. This means that, within that range of compression, the pressure of the canted coil spring against the surface of the channel 54 on one side, and the surface 51 or 53 of the frame member on the other side can be a known value. The significance of this will be explained In any electrical connection in which continuity is maintained by physical contact only, there will be a minimum pressure required between the conductive elements to maintain that continuity. The degree of pressure depends upon such factors as the composition of the conductors, the surface area of the contact, the voltage and current to be transmitted, etc. In the case of the canted coil spring, the spring can be designed and manufactured to provide a known and constant pressure within the compression range as previously described. The significance of this is that this allows a high degree of tolerance for variations in the dimensions A and B, while maintaining continuity in the electrical circuit.

FIGS. 5 and 6 show a canted coil spring 52 mounted on the printed circuit board 10 as will now be described.

Each of the frame members 4 has positioned thereon a plurality of power supply pads 15. The power supply pads are on the same printed circuit board and held at the same voltage potential.

For example, the printed circuit board 14 has, on the bottom surface thereof, a plurality of power supply pads 15, as shown in FIG. 6. Similarly, on a top surface of the plate 12 are positioned a plurality of conductive pads 15, though not shown for convenience.

The canted coil spring of the present invention is particularly well suited for a power supply connection in which a large amount of power is required, particularly those having either a high current need, a high voltage need, or both. The canted coil spring assembly provides a large surface area contact, so the large currents can be carried without heating or voltage drop. Further, the many coils in the spring ensure a reliable, repeatable connection. Even if one, two, perhaps more than half of the coils were to fail or be damaged, as long as some of the coils remain in good mechanical and electrical contact with the power supply pads 15, then sufficient power will be provided to the circuit at a very low impedance, even if the current draw is extremely high.

The headings provided herein are for convenience only and do not interpret the scope or meaning of the claimed invention.

FIG. 6 shows a circuit carrying substrate, such as a printed circuit board 10 (“PCB”), between a pair of opposed electrical substrates, such as power supplying substrates 12, 14. (Portions of one of the power supplying substrates 12 are broken away to better illustrate the underlying structure.) A set of electrical connectors 16 electrically couple the circuits on the PCB 10 to the power supplying substrates 12, 14. (FIG. 5 omits one of the electrical connectors to better illustrate portions of the PCB 10 underlying the electrical connectors 16.) The PCB 10 is perpendicular to the power supplying substrates 12, 14, permitting the PCB 10 to easily slide in and out of engagement with the power supplying substrates 12,14.

The PCB 10 is formed from one or more layers of an insulating material, such as FR-4 epoxy-fiberglass laminate. The PCB 10 is typically sufficiently thick to form a rigid substrate, although minor amounts of bending or deflection can occur. The circuits take the form of electrically conductive circuit traces 18 (i.e., printed circuits) coupling various electrical and electronic components, such as microprocessors 20. FIG. 1 shows only a few of the circuit traces 18 on a surface 22 of the PCB 10, for purposes of illustration. Each layer of the PCB 10 can also carry circuit traces (not shown) where the PCB 10 is a laminate structure. Through-holes 24 can provide connections between the circuit traces 18 on the opposing surfaces 22 and/or inner layers of the PCB 10.

The PCB 10 also includes conductive areas (i.e., lands) to electrically couple the electrical and electronic components to the circuits. For example, FIG. 6 shows a bonding pad 26 to mount one of the microprocessors 20. (FIG. 6 omits the particular microprocessor to better illustrate the underlying bonding pad 26.) The bonding pad 26 can take the form of any conductor suitable for electrically coupling the particular electrical or electronic component to the circuits. For example, the bonding pad 26 can take the form of a ball grid array for direct attachment of integrated circuits (“ICs”). The bonding pad can alternatively take the form of through-holes for receiving leads from IC packages, or can take the form of other types of lands.

The PCB 10 further includes electrical contacts 28 to couple the circuits to other electrical circuits, such as the power supplying substrates 12, 14. (FIG. 6 omits one of the electrical connectors 16 to better illustrate the underlying electrical contact 28.) The electrical contacts 28 can take the form of a conductive area on one or both surfaces 22 of the PCB 10. The electrical contacts 28 can be formed by depositing a conductive material on the PCB 10 as an integral part of forming the circuit traces 18. The electrical contacts 28 are on fingers 30 that extend from side edges 32 of the PCB 10 to facilitate the electrical and mechanical coupling. The fingers 30 can be formed by recessing portions of the edges 32 on either side of the fingers 30.

The power supplying substrates 12, 14 provide power from a power source (not shown) to the circuits on the PCB 10 through the electrical connectors 16 and traces 18. The power supplying substrates 12, 14 can take the form of a conductive plate, or an insulating plate having a conductive material on an outer surface 18. While shown as a plate, the power supplying substrates 12, 14 can take other forms. For example, the conductive portion can take the form of a linear rail. Similarly, the conductive portion can take the form of a trace or other contact region on a printed circuit board. A plate assures electrical contact without regard to the precise position of the PCB 10 with respect to the power supplying substrates 12, 14.

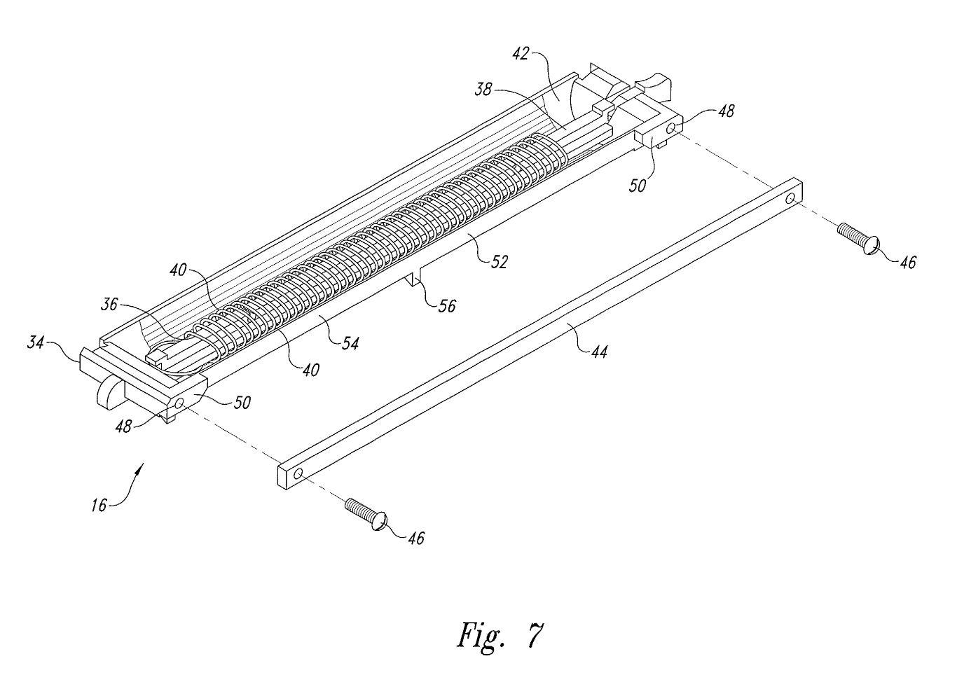

FIG. 7 shows one of the electrical connectors 16, including an elongated channel member 34, a canted coil spring conductor 36 and a retainer 38 received through a perimeter 40 of the canted coil spring conductor 36 to secure the canted coil spring conductor 36 in a channel 42 of the channel member 34. The electrical connector 16 also includes a clamping member 44 and adjustment members, such as threaded fasteners 46. Threaded holes 48 in a bottom surface 50 of the channel member 34 receive the threaded portions of the fasteners 46 to secure the electrical connector 16 to the finger 30 of the PCB 10. The bottom surface 50 of the channel member 34 includes a recess 52 sized and dimensioned to receive the finger 30. A portion of the recessed bottom surface 50 forms a conductive contact surface 54. A leg 56 provides additional support when the channel member 34 is secured to finger 30 of the PCB 10.

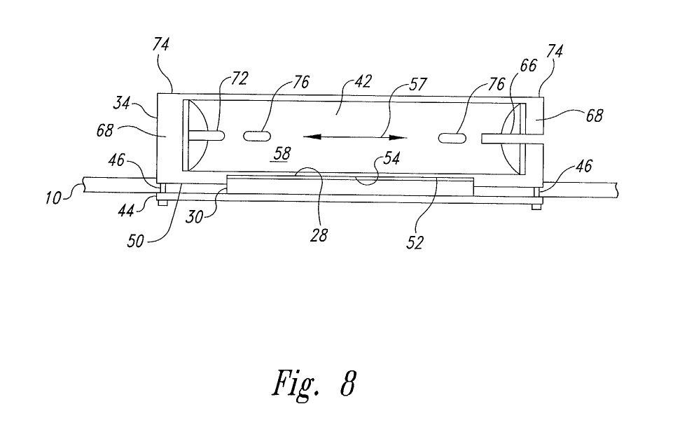

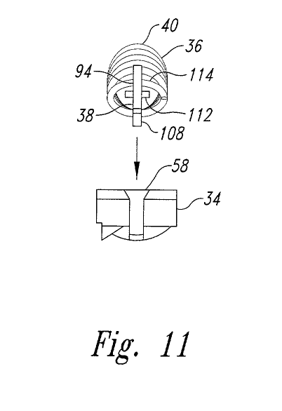

FIG. 8 shows the channel member 34 without the canted coil spring conductor 36 and the retainer 38. The channel 42 has a longitudinal axis 57 extending along a length of the channel 42. At least a portion of the channel 42 forms a conductive channel surface 58 that is in electrical communication with the contact surface 54. The conductive channel surface 58 has an elliptical contour or cross-section that matches the perimeter 40 of the canted coil spring conductor 36 (shown best in FIG. 11). In the shown embodiment, the entire channel member 34, including the channel 42 and the contact surface 54, is a conductor, and can be integrally formed as a gold and nickel plated, aluminum die cast part.

The channel member 34 includes an open slot 66 through a side wall 68 at a first end 70, and a closed slot 72 through the side wall 68 at a second end 74 for receiving respective portions of the retainer 38. The channel member 34 further includes a pair of apertures 76 in the bottom of the channel 42, sized to receive other portions of the retainer 38, as described below.

FIG. 8 shows the channel member 34 secured to the finger 30, where the recess 52 receives the finger 30 between the contact surface 54 of the channel member 34 and the clamping member 44. A head 78 on each of the threaded fasteners 46 engages the clamping member 44 and the thread of the threaded fasteners 46 engage the threaded holes 48 to selectively adjust a distance between the contact surface 54 of the channel member 34 and the clamping member 44. Thus, tightening of the threaded fasteners 54 urges the clamping member 44 toward the bottom surface 50 to effectively clamp the electrical connector 16 to the finger 30 of the PCB 10.

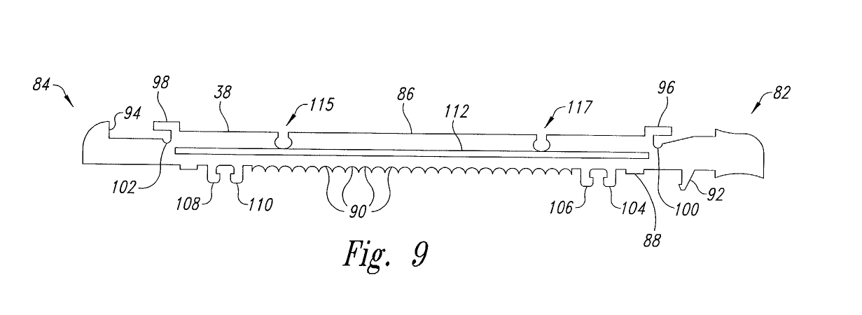

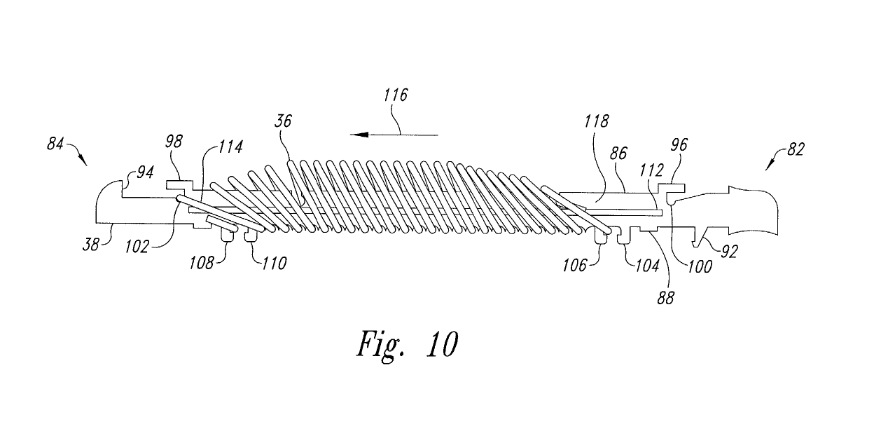

FIG. 9 shows the retainer 38 having a forward end 82 and a rearward end 84 securingly engaging the channel member 16. (The ends 82, 84 are denominated “forward” and “rearward” only for convenience in interpreting the figures, and do not reflect any particular desired orientation for the retainer 38 or the electrical connector 16.) The retainer 38 is an elongated member that can be formed from a variety of materials, for example plastic or metal. A top side 86 of the retainer 38 faces outward from the channel 42, while a bottom side 88 of the retainer 38 faces inward to the channel 42. The bottom side 88 of the retainer 38 includes a plurality of notches 90 sized to receive a respective one of the coils of the canted coil spring conductor 36 (FIG. 10).

The forward end 82 of the retainer 38 includes a downward extending pawl 92 for securingly engaging the channel member 34 through the open slot 66 (FIG. 8). The rearward end 84 of the retainer 38 includes an upright lip 94 for securely engaging the channel member 34 through the closed slot 72. The retainer 38 secures the canted coil spring conductor 36 along the longitudinal axis 57 in the channel 42 of the channel member 34. The pawl 92 allows the retainer 38 and canted coil spring conductor 36 to be removed and replaced, as required.

The retainer 38 includes a forward facing edge or lip 96 on the top side 86 of the retainer 38, close to the forward end 82, and a rearward facing edge or lip 98 on the top side 86 of the retainer 38, close to the rearward end 84. Each of the forward and rearward facing lips 96, 98 overlie a respective notch 100, 102 in the top side 86 of the retainer 38.

The retainer 38 also includes a first pair of opposed edges or lips 104, 106 on the bottom side 88 of the retainer 38, spaced inward from the forward facing lip 96 on the top side 86. The retainer 38 further includes a second pair of opposed edges or lips 108, 110 on the bottom side 88 of the retainer 38, spaced inward from the rearward facing lip 98 on the top side 86. The lips 96, 98, 104-110 on the top and bottom sides 86, 88 of the retainer 38, cooperate to retain the canted coil spring conductor 36 under tension, in a slightly elongated state, as best described with reference to FIGS. 10 and 11. Additionally, the retainer 38 can include a pair of wings 112, to increase the rigidity of the retainer 38.

The grooves 90 on the bottom edge of the retainer advantageously hold the individual coils of the spring 36 in a spaced, known position once the spring is positioned within that channel member 34. Thus, as will be seen in FIG. 10, with the spring in position each of the coils is properly retained in a spaced relationship so that electrical connection can be made along the entire length of the coil spring 36.

FIGS. 10 and 11 show the canted spring coil conductor 36 receiving the retainer 38 within a perimeter 40 of the canted coils. U.S. Pat. Nos. 5,092,781 and 5,069,626 each describe various aspects of canted coil springs. Canted coils springs are generally available through Bal-Seal Engineering Company, of Santa Anna, Calif. The canted coil spring conductor 36 is formed from a conductive material and can be plated with gold. The canted coil spring conductor 36 is particularly suited to coupling power, and is not generally suited to coupling electrical data and/or controls signals due to the large area the canted coil spring occupies on the PCB 10.

The canted coil spring conductor 36 has a leading coil 114 (i.e., the first complete revolution of the canted coil spring conductor 36 in the direction of insertion 116 of the canted coil spring conductor 36 and the PCB 10). Similarly, the canted coil spring conductor 36 has a trailing coil 118 (i.e., the last complete revolution of the canted coil spring conductor 36 in the direction of insertion 114 for the canted coil spring conductor 36 and the PCB 10).

The last trailing edge of the coil 118 is positioned in aperture 117 as shown in FIG. 10. Positioning the last coil on the aperture 117 assists the coil in lying flat when being inserted and removed from the frame to ensure that the coil does not hook onto or become entangled with parts of the frame while it is inserted.

The leading coil 114 of the canted coil spring conductor 36 engages the rearward facing lip 98 on the top side 86 of the retainer 38. The leading coil 114 can rest in the notch 102, underlying the rearward facing lip 98. The leading coil 114 also engages the forward facing lip 108 of the pair of opposed lips 108, 110 on the bottom side 88 of the retainer 38, that are close to the rearward end 84. The rearward facing lip 98 on the top side 86 and forward facing lip 108 on the bottom side 88, thus hold the leading coil 114 substantially flat against the retainer 38 to prevent the canted coil spring conductor 36 from snagging as the PCB 10 is inserted between the power supplying substrates 12, 14. The forward facing lip 106 also retains the coil spring conductor 36 when the PCB 10 is removed from between the power supplying substrate 12, 14, in a direction opposite the direction of insertion 116.

The rearward facing lip 110 of the pair of opposed lips 108, 110 close to the rearward end 84 of the retainer can also engage the leading coil. This further forces the leading coil, and a number of following coils, to lie relatively flat against the retainer 38.

The forward facing lip 106 of the pair of opposed lips 106, 104 on the bottom side 88 of the retainer 38 near the forward end 82 engages the trailing coil 118. The distance between the rearward facing lip 98 on the top side 86 and the forward facing lip on the bottom side 88 is such, that the canted coil spring conductor 36 is slightly elongated from its undeformed state, placing the canted coil spring conductor 36 under tension. The deformed state may enhance the contact between canted coil spring conductor 36 and the conductive channel surface 58, distributing the pressure evenly about the length of the canted coil spring conductor 36.

Thus, the three lips 98, 108 and 106, and the aperture 117, cooperate to retain the canted coiled spring conductor 36 under tension with the leading coil 114 and trailing coil 118 against the retainer 38, where the direction of insertion 116 is towards the rearward end 84 of the retainer 38. The three lips 96, 104 and 110, and the aperture 115, can cooperate to retain the canted coil spring conductor 36 under tension with the coil 118 and coil 114 relatively flat against the retainer 38 when the direction of insertion is opposite to the direction indicated by the arrow 116. The lips 96 and 104 engage the coil 118 (the leading canted coil when referenced with respect to the direction opposite the direction indicated by the arrow 116), while the lip 110 and aperture 115 engages the coil 114 (the trailing canted coil when referenced with respect to the direction opposite the direction indicated by the arrow 116). Thus, the retainer 38 includes two sets of lips 96, 98, 104-110, to permit the electrical connector 16 to couple to either side 32 of the PCB 10.

The retainer assembly as shown in FIG. 9, in combination with the spring as shown in FIG. 10 has a further advantage that it is symmetrically shaped so that it may be easily positioned for insertion or removal or for positioning at different locations on the printed circuit board. For example, if it is desired for the spring to lay in an opposite direction from that shown in FIG. 10. In such an event, the rearward coil would be positioned in aperture 115 with the front coil positioned under lip 96, as has been described.

In particular, FIG. 11 shows the elliptical contour or cross-section of the conductive channel surface 58 of the channel 42 that matches the perimeter 40 of the canted coil spring conductor 36.

Although specific embodiments of and examples for, the invention are described herein for illustrative purposes, various equivalent modifications can be made without departing from the spirit and scope of the invention, as will be recognized by those skilled in the relevant art. The teachings provided herein of the invention can be applied to other electrical connectors, not necessarily the exemplary clamping electrical connector generally described above. For example, the contact surface and channel surface can be discrete, separately defined elements carried by an insulating channel member and coupled by some conductor such as a conductive trace. The electrical conductor can employ channel shapes other than the elliptical cross-section generally shown. The electrical connector can be fastened to portions of the circuit substrate other than a finger, or an edge, and can be fastened using fasteners other than the threaded fastener and clamping member combination generally disclosed. A large number of suitable fasteners are known in the art.

The various embodiments described above can be combined to provide further embodiments. All of the above U.S. patents, patent applications and publications referred to in this specification are incorporated by reference. Aspects of the invention can be modified, if necessary, to employ systems, circuits and concepts of the various patents, applications and publications to provide yet further embodiments of the invention.

These and other changes can be made to the invention in light of the above-detailed description. In general, in the following claims, the terms used should not be construed to limit the invention to the specific embodiments disclosed in the specification and the claims, but should be construed to include all connectors and clamping devices that operate in accordance with the claims. Accordingly, the invention is not limited by the disclosure, but instead its scope is to be determined entirely by the following claims.

We claim:

1. An apparatus comprising:
a frame assembly;
an electrical supply plate positioned on the frame assembly;
a printed circuit board having integrated circuits thereon and adapted to be positioned within the frame assembly;
a coil spring connected to the printed circuit board, the coil spring being positioned on the printed circuit board for contacting the electrical supply plate when the printed circuit board is positioned within the frame assembly to provide power to the printed circuit board.

2. The circuit according to claim 1, further including a channel member connected to the printed circuit board and holding the coil spring within the channel member.

3. The circuit according to claim 1, wherein the coil spring is a canted coil spring.

4. The circuit according to claim 1, wherein the frame assembly includes a first electrical supply plate positioned above the printed circuit assembly board and a second electrical supply plate positioned below the printed circuit board.

5. A method of providing electrical power from a computer frame to a printed circuit board comprising:
moving the printed circuit board in the computer frame assembly;
rubbing an electrically conductive coil spring positioned on the printed circuit board across an electric supply plate mounted in the printed circuit board while moving the printed circuit board in the computer frame assembly so as to improve the electrical contact between the coil springs and the supply plate.

6. The method according to claim 5, wherein the coil spring and the supply plate each include a coating of a highly conductive metal.

7. The method according to claim 6, wherein the metal is hard gold.

8. The method according to claim 5, wherein the coil spring includes copper.

9. The method according to claim 6, wherein the coil spring includes a copper alloy coated in hard gold.

10. The method according to claim 4, further including:
frictionally rubbing a coil spring positioned at the top of the printed circuit board along a first power supply plate and frictionally rubbing a coil spring positioned at the bottom of the printed circuit board along a second power supply plate.
